(19) United States
(12) Patent Application Publication
(10) Pub. No.: US 2017/0089960 A1
(43) Pub. Date: Mar. 30, 2017

(54) ELECTRICITY LOAD DISAGGREGATION

(71) Applicant: FUJITSU LIMITED, Kawasaki-shi (JP)

(72) Inventors: Daisuke MASHIMA, Sunnyvale, CA (US); Mohammad-Mahdi MOAZZAMI, Lansing, MI (US)

(21) Appl. No.: 14/871,286

(22) Filed: Sep. 30, 2015

(51) Int. Cl. G01R 22/10; G01R 21/133

(52) U.S. Cl. CPC G01R 22/10; G01R 21/1333

(57) ABSTRACT

A method of electricity load disaggregation may include identifying a first monitored appliance in an electrical network based on ON/OFF status information. The method may further include identifying a period of time during which the first monitored appliance is on. The method may also include determining whether a second monitored appliance is on during the period of time. The method may include allocating a first load of an aggregate load associated with the period of time to the first monitored appliance in response to determining that the second monitored appliance is not on during the period of time, or in response to determining that the second monitored appliance is on during the period of time, allocating a second load of the aggregate load to the first monitored appliance and allocating a third load of the aggregate load to the second monitored appliance.

### FIELD

The embodiments discussed in the present disclosure are related to electricity load disaggregation.

### BACKGROUND

Nearly every building in the United States, and even throughout the world uses and relies on electrical power. Due to the ubiquitous nature of appliances, there may always be something on or using power in most buildings. The appliances may be any type of device that uses electricity, which may range from microwave ovens to refrigerators, cellular telephone chargers to televisions, and clothes washers to water heaters, to name a few examples.

The subject matter claimed in the present disclosure is not limited to embodiments that solve any disadvantages or that operate only in environments such as those described above. Rather, this background is only provided to illustrate one example technology area where some embodiments described herein may be practiced.

### SUMMARY

One or more embodiments of the present disclosure may include a method of electricity load disaggregation. The method may include identifying a first monitored appliance in an electrical network based on ON/OFF status information. The method may further include identifying a period of time during which the first monitored appliance is on. The method may also include determining whether a second monitored appliance is on during the period of time. The method may include allocating a first load of an aggregate load associated with the period of time to the first monitored appliance in response to determining that the second monitored appliance is not on during the period of time, or in response to determining that the second monitored appliance is on during the period of time, allocating a second load of the aggregate load to the first monitored appliance and allocating a third load of the aggregate load to the second monitored appliance.

The object and advantages of the embodiments will be realized and achieved at least by the elements, features, and combinations particularly pointed out in the claims.

It is to be understood that both the foregoing general description and the following detailed description are given as examples and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1 illustrates an example flow diagram representing a method of disaggregating an electricity load for an electrical network;

FIG. 2 is a diagram representing an example system configured to determine a disaggregated electricity load in an electrical network;

FIG. 3 is a flow diagram of an example method of calculating an average energy usage for a monitored appliance in conjunction with electricity load disaggregation;

FIG. 4 illustrates a flow diagram of a method of disaggregating an electricity load;

FIG. 5 illustrates a flow diagram of another method of disaggregating an electricity load; and

FIG. 6 is a block diagram illustrating an example computing device that is arranged to disaggregate energy load, all arranged in accordance with at least one embodiment described herein.

### DESCRIPTION OF EMBODIMENTS

Electricity is a utility with a limited supply. It may be very expensive to generate electricity and there may be a limited capability to store electricity. Therefore, knowing a current and/or predicted disaggregated electricity consumption (e.g., on a per-appliance basis) may aid an electricity consumer in making power-conscious decisions. Many conventional systems are not capable of providing disaggregated energy electricity load for an electrical network and instead provide an aggregated electricity load that includes electricity load for all appliances in the electrical network. As such, it may be difficult to identify an electricity load for an individual appliance.

Determining the disaggregated electricity load for an electrical network may thus be advantageous for electricity consumers. For example, when made aware of a disaggregated electricity load, electricity consumers may find ways to reduce electricity consumption on a per-appliance basis. Reducing the electricity consumption for any appliance in an electrical network may benefit the electricity consumer by reducing an electricity utility bill while also potentially impacting the environment in a positive way. Providing the electricity consumer with insight into their appliance electricity consumption may also be beneficial in reducing energy usage during peak hours.

Under conventional systems, electricity load disaggregation may be a challenging problem especially when electricity usage information is measured infrequently, (e.g., 15-minute or longer interval), which is typical in many conventional smart meter networks. Moreover, conventional load disaggregation technologies typically are computationally intensive and often are not practical to implement on lower-cost home energy management systems (HEMS) devices or smartphones.

Aspects of the present disclosure address these and other shortcomings by providing a system and method of light-weight electricity load disaggregation using ON/OFF status information of monitored appliances in an electrical network. A “light-weight” process may refer to a process that may need less than an average amount of processing capability, which may allow more devices to perform the light-weight process. Light-weight electricity load disaggregation may be performed by different types of devices of varying processing capabilities, including devices with high-processing capabilities (e.g., dedicated servers) as well as devices with lower-processing capabilities, such as mobile devices. In an electrical network, appliances in the electrical network may be monitored and controlled by a HEMS, which may be a stand-alone device or an application for a mobile device.

In at least one embodiment, the described system and method may determine the disaggregated electricity load based on ON/OFF status information and electrical network-level aggregated energy usage data. The described system and method may receive ON/OFF status information for monitored appliances in the electrical network and aggregated energy consumption data for the electrical network. The described system and method may use the received ON/OFF status information and aggregated energy consumption data to determine a disaggregated electricity load for each monitored appliance in the electrical network. Further, the methods and systems described may not use as much historical data or computational resource as compared to conventional systems. Moreover, methods and systems described may determine disaggregated electricity load near-real time (when near real-time energy consumption data is available) instead of relying primarily on historical data.

As used in the present disclosure, the term “electrical network” may refer to any system, sub-system, household or building (e.g., residential, commercial, industrial) having one or more appliances that are capable of consuming electricity.

As used in the present disclosure, the term “real-time” may mean at or near the present time.

As used in the present disclosure, the term “aggregated electricity load” may refer to a total amount of energy that consumed by all appliances (monitored and unmonitored) in an electrical network. The aggregated electricity load may be over a specific period of time, or may be for a specific point (e.g., snapshot) in time.

As used in the present disclosure, the term “disaggregated electricity load” may refer to an amount of energy that may be consumed by a subset of appliances in the electrical network such that the disaggregated electricity load may include a subset of the aggregated electricity load of the electrical network. Additionally or alternatively, the term disaggregated electricity load may refer to an amount of energy (e.g., a total amount) that may be consumed by a single appliance in the electrical network. Further, as used in the present disclosure, the term “appliance” may refer to any device that is capable of consuming electricity.

As used in the present disclosure, the terms “always-on electrical load” or “always-on load” may refer to an amount of electricity (e.g., power) that may be drawn from an electricity source and that may be consumed regardless of the existence or absence of user presence and activities. As such, the always-on load may indicate a baseline of energy consumption of an appliance, an aggregate of appliances, or an electrical network. In some embodiments, the always-on load may be based on energy consuming appliances whose operation is agnostic to a user operating the appliance (“user-independent appliances”), or energy consuming appliances whose operations may depend on a user operating the appliance (“user-dependent appliances”). For user-dependent appliances, a portion of the energy consumption (e.g., energy consumption during a stand-by period) may be deemed an always-on load while energy consumption during user activities may not be an always-on load.

As used in the present disclosure, the term “monitored appliance” may refer to an appliance that is coupled to a monitor (e.g., internal, external) that may identify the ON/OFF status information the ON/OFF status information of the monitored appliance. The monitor may transmit energy consumption data (e.g., an energy consumption trace) of the monitored appliance to an energy management unit (e.g., HEMS).

Some embodiments described in the present disclosure may relate to determining a disaggregated electricity load for appliances in an electrical network in real-time or close to real-time using ON/OFF status information of one or more monitored appliances and electrical network-level aggregated energy usage data. In at least one embodiment, to determine disaggregated electricity consumption for an appliance, a computing device (e.g., a HEMS) may identify a first monitored appliance in an electrical network. The computing device may further identify a period of time during which the first monitored appliance is on. The computing device may also determine whether a second monitored appliance is on during the period of time. The computing device may allocate a first load of an aggregate load associated with the period of time to the first monitored appliance in response to determining that the second monitored appliance is not on during the period of time. The computing device may allocate a second load of the aggregate load to the first monitored appliance and a third load of the aggregate load to the second monitored appliance in response to determining that the second monitored appliance is on during the period of time. The electrical network may include any number of monitored appliances and the computer device may determine disaggregated electricity consumption for any number of appliances.

In the following description, details are set forth by way of example to facilitate discussion of the disclosed subject matter. The disclosed embodiments are provided by way of example only and are not exhaustive of all possible embodiments. Some embodiments will be explained with reference to the accompanying drawings.

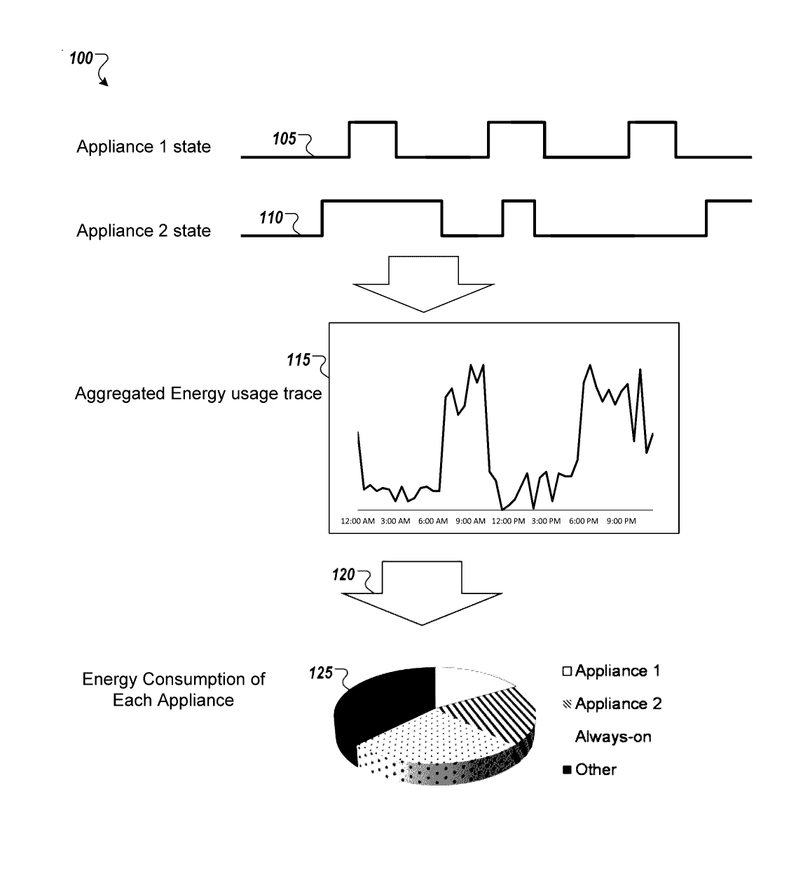

FIG. 1 illustrates an example flow diagram 100 representing a method of disaggregating electricity load for an electrical network. The electrical network may include any number of appliances that consume electricity. As illustrated in FIG. 1, the electrical network may include a first monitored appliance, “Appliance 1,” and a second monitored appliance, “Appliance 2.” The first monitored appliance may consume different amounts of electricity over time, as represented by an Appliance 1 state 105. As illustrated in the Appliance 1 state 105, the first monitored appliance may consume electricity in a step-wise manner in which the first monitored appliance may consume more power when on and less power when off. An Appliance 2 state 110 illustrates an example electricity consumption for the second monitored appliance with a similar step-wise type of energy consumption. When an appliance is OFF, it may be assumed in at least one embodiment that the corresponding appliance is not consuming energy.

The electricity usage for all appliances in the electrical network (e.g., monitored and non-monitored) may be represented as an aggregated energy usage trace 115. The described systems and methods may disaggregate the aggregated energy usage trace 115, as represented by arrow 120. Disaggregation may be performed periodically in a batch, or in near real-time.

An example resulting disaggregated electricity load is represented in the pie chart 125 that illustrates energy consumption of appliances within an electrical network. As illustrated, the pie chart 125 illustrates energy usage for the first monitored appliance, energy usage for the second monitored appliance, an “always-on” energy usage and an “other” energy usage. The pie chart 125 may illustrate energy usage for any number of monitored appliances, which may exclude any always-on energy usage for the respective monitored appliance. The always-on energy usage may optionally be displayed and may include aggregate or average always-on usage information from one or more appliances (e.g., monitored, non-monitored) in the electrical network. The always-on energy usage may represent energy consumption of any appliance (monitored, not monitored) when they are idle or in a standby mode. The “other energy usage” may optionally be displayed and may include energy usage for non-monitored appliances which may be difficult to disaggregate from the aggregate load. Described are various methods and systems of disaggregating electricity load for an electrical network.

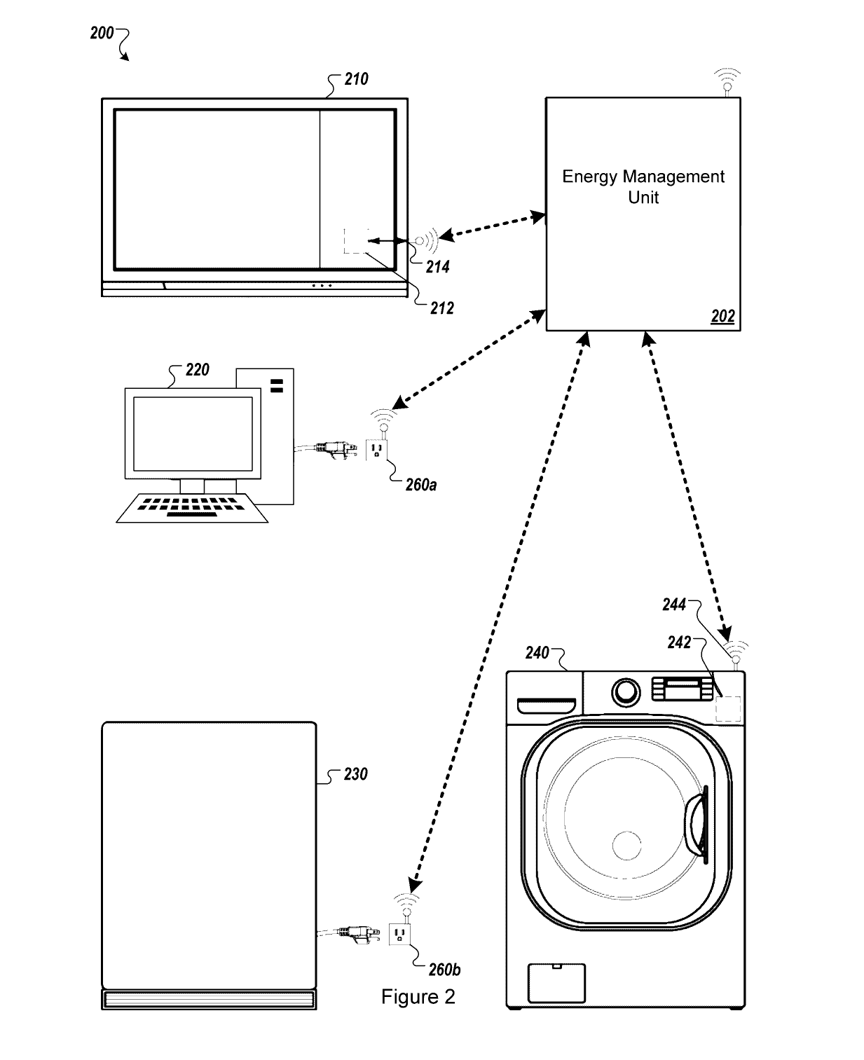

FIG. 2 is a diagram representing an example system 200 configured to determine disaggregated electricity load in an electrical network, according to at least one embodiment of the present disclosure. The system 200 may include an energy management unit 202 configured to determine the always-on load of an electrical network and/or one or more appliances. The system 200 may also include a set of example appliances of the electrical network: a microwave 210, a computer 220, an air conditioning unit 230, and a washing machine 240. Some appliances, such as the microwave 210, may include a monitor 212 for measuring ON/OFF status information of the appliance and a communication component 214 for communicating with the energy management unit 202. In at least one embodiment, the monitor 212 (e.g., smart outlet) may determine the ON/OFF status information status of the monitored appliance based on energy consumption it measures with respect to the monitored appliance. For example, when the energy consumption of the monitored appliance is above a threshold level, the monitor may determine that that the monitored appliance is ON. Similarly, when the energy consumption of the monitored appliance is below a threshold level, the monitor may determine that that the monitored appliance is OFF. The washing machine 240 is also illustrated as having a monitor 242 and a communication component 244. In some embodiments, some appliances, such as the computer 220 may not be equipped with a monitor. In these or other embodiments, the computer 220 may be plugged in to a stand-alone device, such as a smart outlet 260a that may include a monitoring component and a communication component, which may perform similar functionality as the monitor 212 and the communication component 214 of the microwave 210. The air conditioning unit 230 may also be plugged in to a smart outlet 260b. The sum of the energy consumed by each appliance may be used as the aggregated electricity load of the electrical network (e.g., aggregated electricity load of the microwave 210, the computer 220, the air conditioning unit 230, and the washing machine 240). In at least one embodiment, the energy management unit 202 may periodically check a status of each monitored appliance. In embodiments, where the energy management unit 202 is a HEMS and is used to control appliances, the HEMS may log ON/OFF control events for any of the monitored appliances.

In some embodiments, the energy management unit 202 may include one or more processors, a memory, and network communication capabilities. In some embodiments, the energy management unit 202 may be implemented using hardware including a field-programmable gate array (FPGA) or an application-specific integrated circuit (ASIC). In some other instances, the energy management unit 202 may be implemented using a combination of hardware and software. In at least some embodiments, the energy management unit 202 may be any type of user device, such as a personal computer (PC), laptop, mobile phone, smart phone, set top box, tablet computer, netbook computer, e-reader, personal digital assistant (PDA), or cellular phone, or a software application installed thereon, etc.

In the energy management unit 202, data sets including electricity usage and load data, or portions thereof as well as other messages and information may be communicated between the energy management unit 202 and a data storage (not illustrated). The energy management unit 202 may be communicatively coupled to the data storage. For example, the data storage may be hard wired to the energy management unit 202. In other embodiments, the data storage may be in data communication with the energy management unit 202 over a network (not illustrated).

The network may be configured with wired or wireless elements, and may have numerous configurations including a star configuration, token ring configuration, or other configurations. The network may include a local area network (LAN), a wide area network (WAN) (e.g., the Internet), and/or other interconnected data paths across which multiple devices may communicate. In some embodiments, the network may include a peer-to-peer network. The network may also be coupled to or include portions of a telecommunications network that may enable communication of data in a variety of different communication protocols. In some embodiments, the network may include BLUETOOTH® communication networks and/or cellular communication networks for sending and receiving data via short messaging service (SMS), multimedia messaging service (MMS), hypertext transfer protocol (HTTP), direct data connection, wireless application protocol (WAP), e-mail, etc. The data storage may be included in the energy management unit 202 or may be separate from the energy management unit 202.

The data storage may include a removable storage device, a non-removable device, or a combination thereof. Examples of removable storage and non-removable storage devices include magnetic disk devices such as flexible disk drives and hard-disk drives (HDDs), optical disk drives such as compact disk (CD) drives or digital versatile disk (DVD) drives, solid state drives (SSDs), and tape drives to name a few. Example computer storage media may include volatile and nonvolatile, removable and non-removable media implemented in any method or technology for storage of information, such as computer-readable instructions, data structures, program modules, or other data. In some embodiments, the data storage includes a relational database and each appliance and its respective electricity usage and/or load is stored in the data storage in association with an identifier of the appliance.

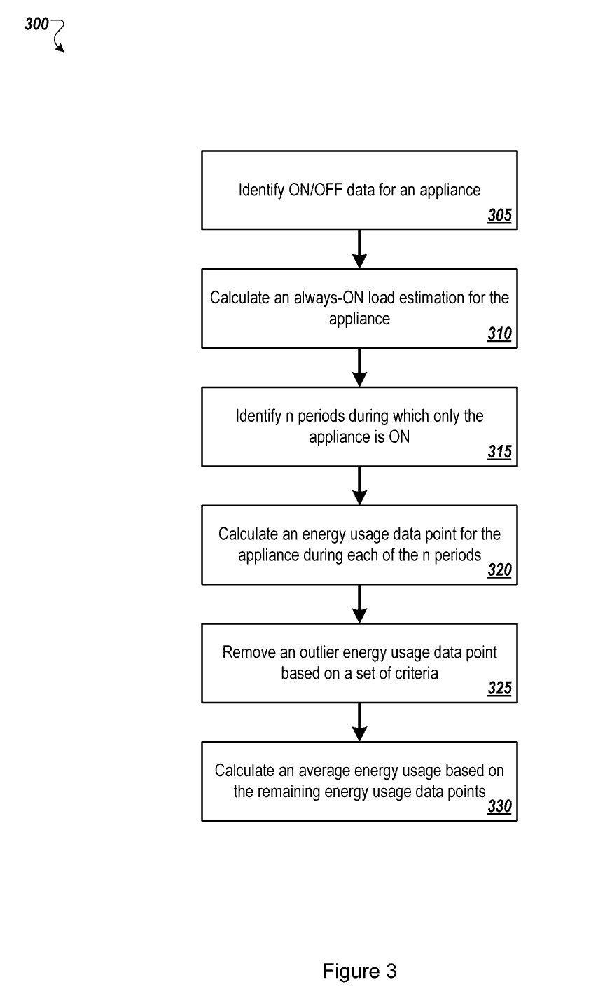

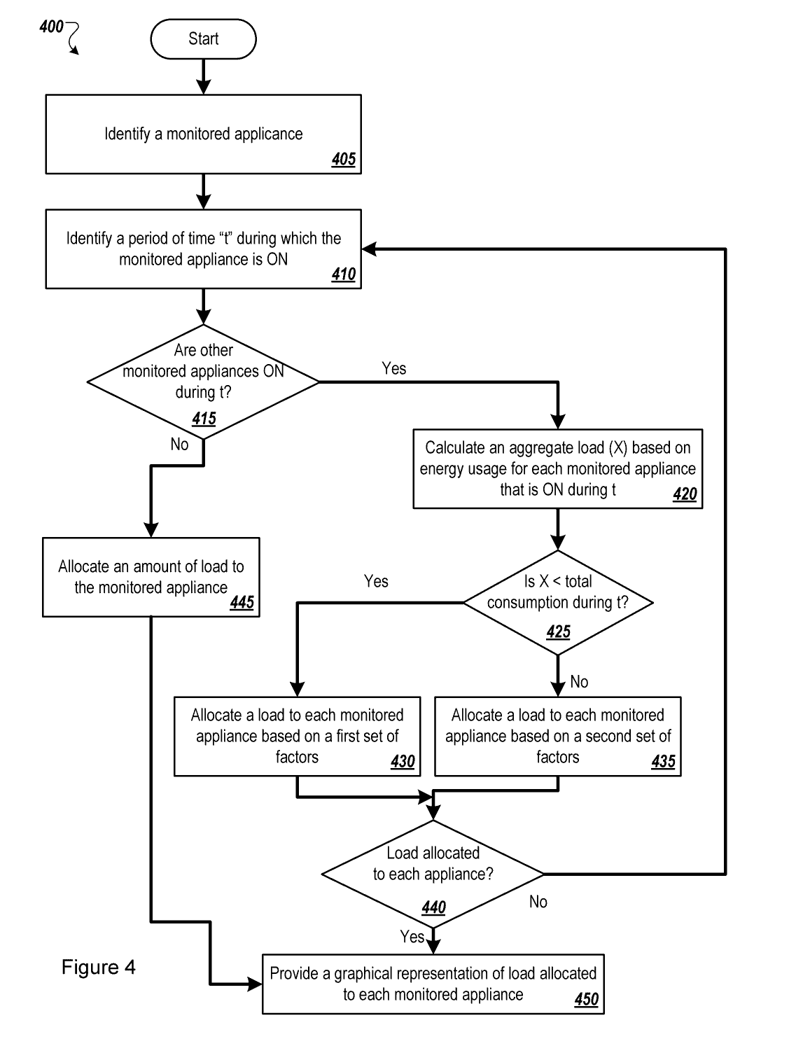

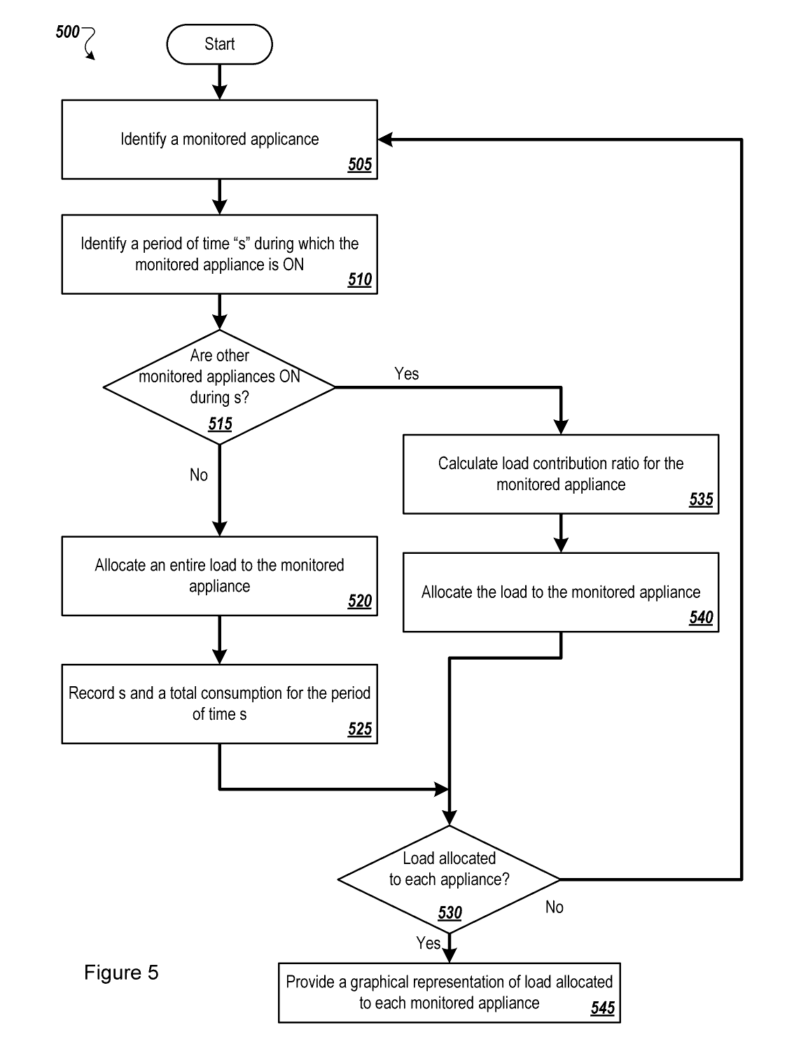

The energy management unit 202 depicted in FIG. 2 may be configured to calculate an average energy usage for a monitored appliance, as further described in conjunction with FIG. 3. Further, the energy management unit 202 may be configured to disaggregate electricity load for one or more monitored appliances, as further described in conjunction with FIGS. 4-5.

The operation of the energy management unit 202 with respect to each of the appliances may be similar. The example operation of the energy management unit 202 may be described with respect to the microwave 210, but the same disclosure may be applicable to the computer 220, the air conditioning unit 230, or the washing machine 240. The monitor 212 may measure the ON/OFF status information of the microwave 210. The communication component 214 may transmit the ON/OFF status information of the microwave 210 to the energy management unit 202. For example, the communication component 214 may transmit the ON/OFF status information once per day, multiple times per day, once per week, etc. The communication component 214 may continuously send the ON/OFF status information to the energy management unit 202 The energy management unit 202 may periodically poll the monitored appliances for their respective ON/OFF status information.

After receipt of ON/OFF status information for different appliances, the energy management unit 202 may determine an average energy usage for one or more appliances based on the ON/OFF status information. Additionally or alternatively, the energy management unit 202 may determine an average disaggregated electricity load for the electrical network.

By way of example, for appliances where a user operating the appliance may not actively control the operating state of the appliance, all or substantially all of the corresponding energy consumption of the appliance may be excluded from the disaggregated electricity load. User-independent appliances may include, for example, typical refrigerators or freezers. For example, for a refrigerator without an icemaker, the electricity consumption of the refrigerator may occur when the compressor turns on or off to cool the inside of the refrigerator. The operation of the compressor may occur independently of a user turning on or off the compressor. While there may be certain features of refrigerators that may depend on user interaction with the appliance (e.g. a light turning on when a door is opened or a user turning on an ice maker), the operation of a refrigerator left alone with a door closed serves to illustrate a user-independent appliance.

In at least some embodiments, always-on load may be removed as part of a process to disaggregate electricity load. By way of example, for appliances whose operation state, and consequently power consumption, depend on user activity, a portion of power consumption may be excluded from the disaggregated electricity load. The portion excluded may be the portion of the consumption that is always present such as an idle state (e.g., stand-by state), while the active state may be included. For example the microwave 210 may consume a certain amount of power even when turned off (contributing to the always-on load) and may consume a much larger amount of power when a TV program is watched. User-dependent appliances may include, for example; TVs, computers, cable boxes, microwave ovens, or radios. In these and other embodiments, the always-on load of user-dependent appliances may include the energy consumption of the user-dependent appliances when they are idle or in a standby mode.

The energy management unit 202 may also provide a graphical representation of the disaggregated electricity load for the electrical network. For example, the energy management unit 202 may provide the graphical representation of the disaggregated electricity load via a graphical user interface (GUI) on an electronic display. The graphical representation may include a historical or real-time representation of energy-usage data, which may help the electricity consumer increase awareness of power consumption by different appliances. In at least some embodiments, the energy management unit 202, may provide a graphical representation that illustrates how much energy cost may have been saved as a result of an appliance recently being turned off. In some embodiments, the GUI that may receive the representations may be included with the energy management unit 202 or with another device (e.g., a tablet computer, a smartphone, etc.).

In some embodiments, there may be fewer smart outlets 260 than appliances contributing to the aggregated electricity load, or a system may not include smart outlets 260. In these and other embodiments, the energy management unit 202 may receive, aggregate, collect, or otherwise generate data for an energy consumption trace for the electrical network from respective monitors 212. For example, a smart electricity meter for the electrical network may provide an energy consumption trace, for example, via a cloud-based energy monitor. Some cloud-based energy monitors may monitor, measure, and control aggregated electricity load for monitored appliances, irrespective of whether the monitored appliances is connected to a smart outlet 260. For example, a monitored appliance may have a wired or wireless monitor 212 that communicates with the energy management unit 202 without being connected to a smart outlet 260. An example, cloud-based energy monitor may include a GREEN BUTTON® service. Additionally or alternatively, the energy management unit 202 may receive, aggregate, collect, or otherwise generate data based on a home area network (HAN) device such as a RAINFOREST EAGLE™ device, a home/building energy management system (HEMS/BEMS), etc., which may provide aggregated energy consumption data for the electrical network. Additionally or alternatively, the energy management unit 202 may be part of a HAN or HEMS/BEMS.

Modifications, additions, or omissions may be made to the system 200 without departing from the scope of the present disclosure. For example, in some embodiments, the system 200 may include any number of other components that may not be explicitly illustrated or described. For example, the system 200 may include any number of appliances and/or smart outlets. As another example, the energy management unit 202 may be located locally to the electrical network of appliances, or may be located remotely, for example, at an electricity provider. As another example, the system 200 may include appliances that do not provide their energy consumption to the energy management unit 202.

Moreover, the separation of various components in the embodiments described in the present disclosure is not meant to indicate that the separation occurs in all embodiments. It may be understood with the benefit of this disclosure that the described components may be integrated together in a single component or separated into multiple components.

FIGS. 3-5 are flow diagrams of various methods related to disaggregating electricity load. The methods may be performed by processing logic that may include hardware (circuitry, dedicated logic, etc.), software (such as is run on a general purpose computer system or a dedicated machine), or a combination of both, which processing logic may be included in the energy management unit 202 or another computer system or device. For simplicity of explanation, methods described in the present disclosure are depicted and described as a series of acts. However, acts in accordance with this disclosure may occur in various orders and/or concurrently, and with other acts not presented and described herein. Further, not all illustrated acts may be required to implement the methods in accordance with the disclosed subject matter. In addition, the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used in the present disclosure, is intended to encompass a computer program accessible from any computer-readable device or storage media. The methods illustrated and described in conjunction with FIGS. 3-5 may be performed, for example, by a computing system such as the energy management unit 202 of FIG. 2. For clarity of presentation, the description that follows uses the energy management unit 202 as examples for describing the methods. However, another system, or combination of systems, may be used to perform the methods.

FIG. 3 is a flow diagram of an example method 300 of calculating an average energy usage for a monitored appliance for use during electricity load disaggregation, according to at least one embodiment of the present disclosure. The method 300 may begin at block 305 where the processing logic may identify ON/OFF status information for a monitored appliance. The ON/OFF status information may be stored in a data storage. In some embodiments, the processing logic may receive the ON/OFF status information for the monitored appliance from a data storage. In some embodiments, the ON/OFF status information may be stored in the data storage in association with an identifier for the monitored appliance. The ON/OFF status information may be retrieved from the data storage using the identifier for the monitored appliance. The ON/OFF status information may indicate periods of time during which the monitored appliance is powered on and powered off. In at least some embodiments, a powered off state may include a standby state where the monitored appliance is in a low-power consumption mode. In at least some embodiments, the processing logic may receive ON/OFF status information from an energy management unit (e.g., energy management unit 202) that monitors the monitored appliance. In at least some embodiments, a monitored appliance may send the ON/OFF status information to the processing logic or to a data storage that is accessible by the processing logic. The processing logic may also receive household-level aggregated energy consumption data, such as from a smart meter, GREEN BUTTON® service, a home area network (HAN) device such as a RAINFOREST EAGLE™ device, etc.

At block 310, the processing logic may calculate an always-ON load for all appliances in an electrical network. In some embodiments, to calculate an always-on load for the electrical network, an energy consumption trace (e.g., historical or real time) may be parsed into one or more segments of time using change point detection techniques, the change points designating shifts from one segment to the next segment. The segments may be analyzed to find one or more segments representative of the always-on load. For example, the segment with the lowest average value may be selected as the representative segment, or multiple consecutive segments with the lowest average may be selected. The representative one or more segments may be used to determine the always-on load for a period of time, such as a day, a week, a month, etc. In at least one embodiment, the processing logic may calculate an always-ON estimation based on methods and systems described in U.S. patent application Ser. No. 14/857,714 filed on Sep. 17, 2015, entitled “Determining Electrical Loads,” the entire contents of which are incorporated by reference.

At block 315, the processing logic may identify “n” periods during which the monitored appliance is ON. The variable “n” may include any number. In at least some embodiments, the processing logic may use the ON/OFF status information received at block 305 to identify “n” periods during which the monitored appliance is ON. Although multiple appliances may be ON at the same time, the processing logic may assume that the entire ON periods for different appliances do not overlap (i.e., at least some portion of ON periods are not overlapping with other monitored appliances). The processing logic may use non-overlapping portions for the calculations described below. In at least some embodiments, when the entire ON periods for different appliances overlap, the processing logic may not be able to separate the energy consumption for each of the overlapping appliances. In such cases, the processing logic may ignore the overlapping appliances or rely on external information (e.g., a catalogue or specification) to identify general energy consumption of each overlapping appliance. As the processing logic collects more ON/OFF status information, the processing logic may have enough data to be able to separate the energy consumption for each of the overlapping appliances. In at least one embodiment, the processing logic may request that a user operate one monitored appliance at a time on as part of a training program. In at least some embodiments, the granularity of energy usage data may be smaller than a time granularity of an ON/OFF duration. For example, a smart meter may collect electricity usage data for a computer at 15-minute or longer intervals, (e.g., 1:00, 1:15, 1:30) but the computer may be turned on at any time (e.g., at 1:05). In at least one embodiment, an ON/OFF event may be recorded at substantially the time the ON/OFF event happens (e.g., at 1:05). If only appliance 1 is ON during 1:00-1:15 and appliance 1 is actually turned on at 1:05, the processing logic may allocate ⅔ of the energy consumption of 1:00-1:15 slot to the appliance 1 and used for average calculation.

At block 320, the processing logic may calculate an energy usage data point for the appliance during each of the periods during which the appliance is ON. The energy usage data point may be an instant power for the appliance at for the respective period. To calculate an energy usage data point for the appliance during a period, the processing logic may divide the energy usage during the period by the duration of the period. The processing logic may calculate an energy usage data point for the appliance during each of the ON periods determined at block 315.

At block 325, the processing logic may remove any number of outlier energy usage data points based on a set of criteria. In at least one embodiment, the set of criteria may include one or more threshold values. The processing logic may remove a number of energy usage data points that are above a threshold amount or percentage. For example, the processing logic may remove the top two, or the top 5% of the energy usage data points. Since at least some embodiments may include unmonitored appliances that were on during the ON period of interest, the energy usage of the unmonitored appliance may inflate the energy usage data point calculated at block 320. Thus, removing some of the outlier energy usage data points may decrease any impact the unmonitored appliance may have on the energy usage data point.

At block 330, the processing logic may calculate an average energy usage for the appliance based on the remaining energy usage data points. The processing logic may store the average energy usage in a data storage in association with an identifier for the respective monitored appliance.

The processing logic may repeat blocks 305 through 330 for all monitored appliances. In at least some embodiments, the processing logic may periodically and/or continuously repeat blocks 305 through 330 to calculate average energy usages for each appliance in an electrical network. The processing logic may store each average energy usage in association with its respective monitored appliance.

FIG. 4 illustrates a flow diagram of a method 400 for disaggregating electricity load, according to at least one embodiment of the present disclosure. The method 400 may be implemented in any energy management system. In at least some embodiments, the method 400 may be implemented in an electrical network with a limited number of monitored appliances.

The method 400 may begin at block 405 where processing logic may identify a monitored appliance. In at least some embodiments, the processing logic may identify monitored appliances by accessing a data structure that includes information for any monitored appliances within an electrical network. In at least some embodiments, the processing logic receives messages (e.g., heartbeat, hello) from the monitored appliances within the electrical network and may use the messages to identify the monitored appliances. In at least one embodiment, the processing logic may receive ON/OFF status information for one or more monitored appliances and household-level aggregated energy consumption data. In at least one embodiment, the processing logic may subtract an always-on load from the household-level aggregated energy consumption data.

At block 410, the processing logic may identify a period of time “t” during which a monitored appliance is ON, as described in conjunction with block 315 of FIG. 3.

At block 415, the processing logic may determine whether other monitored appliances are ON during the period of time “t.” In response to no other monitored appliances being ON during the period of time “t” (“NO” at block 415), at block 445 the processing logic may allocate an amount of load to the monitored appliance. In at least one embodiment, the processing logic may allocate an average energy usage for the monitored appliance, which may be the average energy usage for the monitored appliance determined at block 330 of FIG. 3. In at least some embodiments, when there is one monitored appliance that is ON during time t, the processing logic may allocate all of the load for the period of time t to the one monitored appliance. At block 450, the processing logic may provide a graphical representation of load allocated to each monitored appliance. In at least some embodiments, the graphical representation is a graphical user interface (GIU). In at least some embodiments, the processing logic may provide a graphical representation of a total load associated with the period of time on a per-appliance basis. For example, the graphical representation may include a list of appliances and their respective loads during the period of time t.

In response to the processing logic identifying other monitored appliances that are ON during the period of time “t” (“YES” at block 415), at block 420 the processing logic may calculate an aggregate load “X” based on energy usage for each monitored appliance that is ON during the period of time “t.” In at least some embodiments, the processing logic may use the average energy usage for each appliance determined at block 330 of FIG. 3 to calculate the aggregate load X. For example, X may be calculated as follows:

X=E[P1]*t+E[P2]*t+ . . . +E[Pm]*t),

in the above expression E[P1]=average energy usage for a first monitored appliance, E[P2]=average energy usage for a second monitored appliance, E[Pm]=average energy usage for an “m-th” monitored appliance, where m is the number of monitored appliances in the electrical network.

At block 425, the processing logic may determine whether X is less than a total power consumption during the period of time “t.” In response to X being less than the total power consumption of the period of time “t” (“YES” at block 425), at block 430 the processing logic may allocate a load to each monitored appliance based on a first set of energy consumption factors. In at least some embodiments, the first set of energy consumption factors includes the average energy usage E[Pk]*t and the processing logic may allocate the result of the average energy usage E[Pk]*t to each appliance, where k is an index number of a monitored appliance. In response to X not being less than or equal to the total power consumption of the period of time “t” (“NO” at block 425), at block 435 the processing logic may allocate a load to each monitored appliance based on a second set of energy consumption factors. In at least some embodiments, the second set of energy consumption factors may include the equation:

{E[Pk]*t/X}*{total consumption of the period} to appliance k.

At block 440, the processing logic may determine whether a load has been allocated to each monitored appliance within the electrical network. In response to a load not being allocated to each monitored appliance within the electrical network (“NO” at block 440), the processing logic may loop to block 410. After a load has been allocated to each monitored appliance within the electrical network, the processing logic may allocate any leftover load to an “other” load. In response to a load having been allocated to each monitored appliance within the electrical network (“YES” at block 440), at block 450 the processing logic may provide a graphical representation of load allocated to each monitored appliance, as described above.

FIG. 5 illustrates a flow diagram of another method 500 of disaggregating electricity load, according to at least one embodiment of the present disclosure. The method 500 may be implemented in any energy management system. In at least some embodiments, the method 500 may be implemented in an electrical network when most or all of the appliance within an electrical network are managed appliances.

The method 500 may begin at block 505 where processing logic may identify a monitored appliance, as further described in conjunction with block 405 of FIG. 4.

At block 510, the processing logic may identify a period of time “s” during which a monitored appliance is ON, as described in conjunction with block 315 of FIG. 3.

At block 515, the processing logic may determine whether other monitored appliances are ON during the period of time “s.” In response to no other monitored appliances are ON during the period of time “s” (“NO” at block 515), at block 520 the processing logic may allocate an entire load associated with the period of time “s” to the monitored appliance. At block 525, the processing logic may record the period of time “s” and the total consumption for the period of time “s” in a data storage.

At block 530, the processing logic may determine whether a load has been allocated to each monitored appliance within the electrical network. In response to a load not having been allocated to each monitored appliance within the electrical network (“NO” at block 530), the processing logic may loop to block 505. In response to a load having been allocated to each monitored appliance within the electrical network (“YES” at block 530), at block 545 the processing logic may provide a graphical representation of load allocated to each monitored appliance, as described above with respect to FIG. 4.

In response to the processing logic identifying other monitored appliances that are ON during the period of time “s” (“YES” at block 515), at block 535 the processing logic may calculate a load contribution ratio for the monitored appliance. Since there may be other monitored appliances that are ON during the period of time “s”, the processing logic may disaggregate the loads within the period of time “s” on a per-appliance basis based on a ratio of contribution of energy consumption during the period of time “s”. The processing logic may identify a sub-period of time during the period of time “s” during which at least two monitored appliances are ON. The sub-period of time may be referred to as an overlapping area. The processing logic may disaggregate loads in the overlapping area relative to the average energy usage for each monitored appliance. The average energy usage may be derived using the method further described in conjunction with FIG. 3.

In some embodiments, the processing logic may calculate the load contribution ratio for each monitored appliance by normalizing an expected value of the instant power consumption of a monitored appliance during the period of time “s.” The processing logic may compute the expected value based on the non-overlapping events of the monitored appliance. In at least some embodiments, the processing logic may calculate the load contribution ratio for a monitored appliance “k” using the following equation:

$${ratio}_{k} = \frac{E [ {P}_{k} ]}{{\sum }_{j} E [ {P}_{j} ]} ,$$

where E [Pₖ] is the average energy usage for that monitored appliance, and where “j” is the total number of monitored appliances that are ON during the period of time “s.”

At block 540, the processing logic may allocate the load contribution ratio*total load during the period of time “s” to the monitored appliance. In at least some embodiments, the processing logic may store the calculated load contribution ratio to a data storage. The processing logic may proceed to block 530, as described above.

For this and other processes and methods disclosed in the present disclosure, the functions performed in the processes and methods may be implemented in differing order. Further, the outlined steps and operations are only provided as examples, and some of the steps and operations may be optional, combined into fewer steps and operations, or expanded into additional steps and operations without detracting from the essence of the disclosed implementations.

The embodiments described in the present disclosure may include the use of a special-purpose or general-purpose computer including various computer hardware or software modules, as discussed in greater detail below.

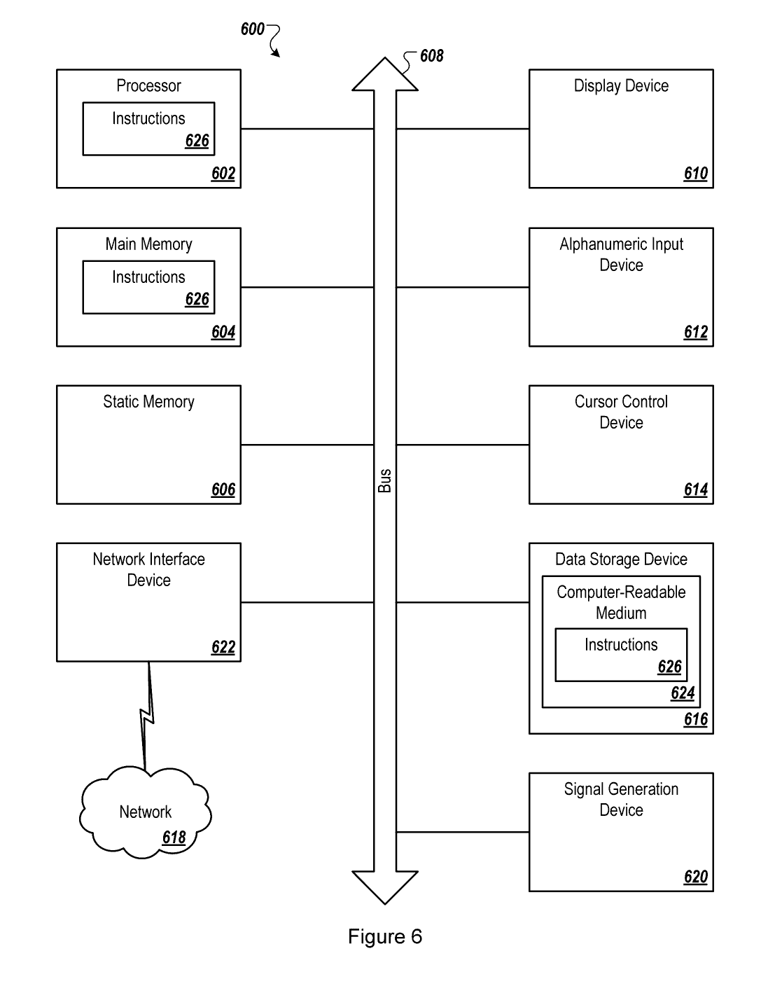

FIG. 6 is a block diagram illustrating an example computing system 600 that is arranged for disaggregation of energy load, according to at least one embodiment of the present disclosure. In some embodiments, an energy management unit (e.g., the energy management unit 202 of FIG. 2) may include the computing system 600. The computing system 600 may include a mobile phone, a smart phone, a netbook computer, a rackmount server, a router computer, a server computer, a personal computer, a mainframe computer, a laptop computer, a tablet computer, a desktop computer etc., within which a set of instructions, for causing the machine to perform any one or more of the methodologies discussed herein, may be executed. In alternative embodiments, the machine may be connected (e.g., networked) to other machines in a LAN, an intranet, an extranet, or the Internet. The machine may operate in the capacity of a server machine in client-server network environment. The machine may be a personal computer (PC), a set-top box (STB), a server, a network router, switch or bridge, or any machine capable of executing a set of instructions (sequential or otherwise) that specify actions to be taken by that machine. Further, while only a single machine is illustrated, the term “machine” may also include any collection of machines that individually or jointly execute a set (or multiple sets) of instructions to perform any one or more of the methodologies discussed herein.

The computing system 600 includes a processing device (e.g., a processor) 602, a main memory 604 (e.g., read-only memory (ROM), flash memory, dynamic random access memory (DRAM) such as synchronous DRAM (SDRAM)), a static memory 606 (e.g., flash memory, static random access memory (SRAM)) and a data storage device 616, which communicate with each other via a bus 608.

Processing device 602 represents one or more general-purpose processing devices such as a microprocessor, central processing unit, or the like. More particularly, the processing device 602 may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 602 may also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein.

The computing system 600 may further include a network interface device 622 which may communicate with a network 618. The computing system 600 also may include a display device 610 (e.g., a liquid crystal display (LCD) or a cathode ray tube (CRT)), an alphanumeric input device 612 (e.g., a keyboard), a cursor control device 614 (e.g., a mouse) and a signal generation device 620 (e.g., a speaker). In one implementation, the display device 610, the alphanumeric input device 612, and the cursor control device 614 may be combined into a single component or device (e.g., an LCD touch screen).

The data storage device 616 may include a computer-readable storage medium 624 on which is stored one or more sets of instructions 626 (e.g., system 106) embodying any one or more of the methodologies or functions described herein. The instructions 626 may also reside, completely or at least partially, within the main memory 604 and/or within the processing device 602 during execution thereof by the computing system 600, the main memory 604 and the processing device 602 also constituting computer-readable media. The instructions may further be transmitted or received over a network 618 via the network interface device 622.

While the computer-readable storage medium 626 is shown in an example embodiment to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methodologies of the present disclosure. The term “computer-readable storage medium” may accordingly be taken to include, but not be limited to, solid-state memories, optical media and magnetic media.

The network interface device 622 may include a network controller, which may be arranged to facilitate communications with one or more other computing devices over a network communication link via one or more communication ports.

The network communication link may be one example of a communication media. Communication media may typically be embodied by computer-readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR), and other wireless media. The term “computer-readable media” as used herein may include both storage media and communication media.

The computing system 600 may be implemented as a portion of a small-form factor portable (or mobile) electronic device such as a smartphone, a personal data assistant (PDA), or an application-specific device. The computing system 600 may also be implemented as a personal computer including both laptop computer and non-laptop computer configurations, or a server computer including both rack-mounted server computer and blade server computer configurations.

As indicated above, embodiments described in the present disclosure may be implemented using computer-readable media for carrying or having computer-executable instructions or data structures stored thereon. Such computer-readable media may be any available media that may be accessed by a general-purpose or special-purpose computer. By way of example, and not limitation, such computer-readable media may include non-transitory computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, flash memory devices (e.g., solid state memory devices), or any other storage medium which may be used to carry or store program code in the form of computer-executable instructions or data structures and which may be accessed by a general-purpose or special-purpose computer. Combinations of the above may also be included within the scope of computer-readable media.

Computer-executable instructions may include, for example, instructions and data which cause a general-purpose computer, special-purpose computer, or special-purpose processing device (e.g., one or more processors) to perform a certain function or group of functions. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

As used herein, the terms “module” or “component” may refer to specific hardware implementations configured to perform the operations of the module or component and/or software objects or software routines that may be stored on and/or executed by general-purpose hardware (e.g., computer-readable media, processing devices, etc.) of the computing system. In some embodiments, the different components, modules, engines, and services described herein may be implemented as objects or processes that execute on the computing system (e.g., as separate threads). While some of the system and methods described herein are generally described as being implemented in software (stored on and/or executed by general-purpose hardware), specific hardware implementations or a combination of software and specific hardware implementations are also possible and contemplated. In this description, a “computing entity” may be any computing system as previously defined herein, or any module or combination of modulates running on a computing system.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present inventions have been described in detail, various changes, substitutions, and alterations could be made hereto without departing from the spirit and scope of the invention.

What is claimed is:

1. A method comprising:
identifying a first monitored appliance in an electrical network based on ON/OFF status information;
identifying a period of time during which the first monitored appliance is on;
determining whether a second monitored appliance is on during the period of time;
in response to determining that the second monitored appliance is not on during the period of time, allocating a first load of an aggregate load associated with the period of time to the first monitored appliance; or
in response to determining that the second monitored appliance is on during the period of time:
allocating a second load of the aggregate load to the first monitored appliance; and
allocating a third load of the aggregate load to the second monitored appliance.

2. The method of claim 1, wherein allocating the second load of the aggregate load to the first monitored appliance and allocating the third load of the aggregate load to the second monitored appliance comprises:
calculating the aggregate load for the period of time based on a first average energy usage for the first monitored appliance and a second average energy usage for the second monitored appliance;
determining whether the aggregate load is less than a total power consumption for the period of time;
in response to the aggregate load being less than the total power consumption for the period of time, calculating the second load of the aggregate load and the third load of the aggregate load based on a first set of energy consumption factors; or
in response to the aggregate load being greater than the total power consumption for the period of time, calculating the second load of the aggregate load and the third load of the aggregate load based on a second set of energy consumption factors.

3. The method of claim 2, wherein the first set of energy consumption factors comprises an average energy usage for the period of time, and wherein the second set of energy consumption factors comprises a total consumption of the period relative to the aggregate load.

4. The method of claim 2 further comprising determining the first average energy usage based on historical data associated with the first monitored appliance.

5. The method of claim 2 further comprising determining the first average energy usage based on on/off data associated with the first monitored appliance.

6. The method of claim 5, wherein determining the first average energy usage based on on/off data associated with the first monitored appliance comprises:
calculating an always-on load estimation for the first monitored appliance;
identifying one or more time periods during which the first monitored appliance is on based on the on/off data;
calculating an energy usage data point for the first monitored appliance during each of the one or more time periods; and
calculating the first average energy usage based on one or more energy usage data points.

7. The method of claim 6, wherein at least one energy usage data point is excluded from the calculating the first average energy usage based on the at least one energy usage data point being an outlier with respect to the other energy usage data points.

8. The method of claim 1, wherein allocating the second load of the aggregate load to the first monitored appliance and allocating the third load of the aggregate load to the second monitored appliance comprises:
calculating a first load contribution ratio for the first monitored appliance and a second load contribution ratio for the second monitored appliance;
calculating the second load for the first monitored appliance based on the first load contribution ratio and a total load associated with the period of time; and
calculating the third load for the second monitored appliance based on the second load contribution ratio and the total load associated with the period of time.

9. The method of claim 1 further comprising providing a graphical representation of a total load associated with the period of time on a per-appliance basis.

10. A system comprising:
a memory; and
a processing device operatively coupled to the memory, the processing device configured to:
identify a first monitored appliance in an electrical network based on ON/OFF status information;
identify a period of time during which the first monitored appliance is on;
determine whether a second monitored appliance is on during the period of time;
allocate a first load associated of an aggregate load with the period of time to the first monitored appliance in response to determining that the second monitored appliance is not on during the period of time; and
allocate a second load of the aggregate load to the first monitored appliance and a third load of the aggregate load to the second monitored appliance in response to determining that the second monitored appliance is on during the period of time.

11. The system of claim 10, wherein when allocating the second load of the aggregate load to the first monitored appliance and allocating the third load of the aggregate load to the second monitored appliance the processing device is configured to:
calculate the aggregate load for the period of time based on a first average energy usage for the first monitored appliance and a second average energy usage for the second monitored appliance;
determine whether the aggregate load is less than a total power consumption for the period of time;
calculate the second load of the aggregate load and the third load of the aggregate load based on a first set of energy consumption factors in response to determining that the aggregate load is less than the total power consumption for the period of time; and
calculate the second load of the aggregate load and the third load of the aggregate load based on a second set of energy consumption factors in response to determining that the aggregate load is greater than the total power consumption for the period of time.

12. The system of claim 11, wherein the processing device is further configured to determine the first average energy usage based on on/off data associated with the first monitored appliance.

13. The system of claim 12, wherein when determining the first average energy usage based on on/off data associated with the first monitored appliance, the processing device is configured to:
calculate an always-on load estimation for the first monitored appliance;
identify one or more time periods during which the first monitored appliance is on based on the on/off data;
calculate an energy usage data point for the first monitored appliance during each of the one or more time periods; and
calculate the first average energy usage based on one or more energy usage data points.

14. The system of claim 10, wherein when allocating the second load of the aggregate load to the first monitored appliance and allocating the third load of the aggregate load to the second monitored appliance, the processing device is configured to:
calculate a first load contribution ratio for the first monitored appliance and a second load contribution ratio for the second monitored appliance;
calculate the second load for the first monitored appliance based on the first load contribution ratio and a total load associated with the period of time; and
calculate the third load for the second monitored appliance based on the second load contribution ratio and the total load associated with the period of time.

15. A non-transitory computer-readable storage medium having stored thereon programming code, which in response to being executed by one or more processors, controls performance of operations comprising:
identifying a first monitored appliance in an electrical network based on ON/OFF status information;
identifying a period of time during which the first monitored appliance is on;
determining whether a second monitored appliance is on during the period of time;
in response to determining that the second monitored appliance is not on during the period of time, allocating a first load of an aggregate load associated with the period of time to the first monitored appliance; or
in response to determining that the second monitored appliance is on during the period of time:
allocating a second load of the aggregate load to the first monitored appliance; and
allocating a third load to the second monitored appliance.

16. The non-transitory computer readable storage medium of claim 15, wherein allocating the second load of the aggregate load to the first monitored appliance and allocating the third load of the aggregate load to the second monitored appliance comprises:
calculating the aggregate load for the period of time based on a first average energy usage for the first monitored appliance and a second average energy usage for the second monitored appliance;
determining whether the aggregate load is less than a total power consumption for the period of time;
in response to the aggregate load being less than the total power consumption for the period of time, calculating the second load of the aggregate load and the third load of the aggregate load based on a first set of energy consumption factors; and
in response to the aggregate load being greater than the total power consumption for the period of time, calculating the second load of the aggregate load and the third load of the aggregate load based on a second set of energy consumption factors.

17. The non-transitory computer readable storage medium of claim 16, the operations further comprising determining the first average energy usage based on on/off data associated with the first monitored appliance.

18. The non-transitory computer readable storage medium of claim 17, wherein determining the first average energy usage based on on/off data associated with the first monitored appliance comprises:
calculating an always-on load estimation for the first monitored appliance;
identifying one or more time periods during which the first monitored appliance is on based on the on/off data;
calculating an energy usage data point for the first monitored appliance during each of the one or more time periods; and
calculating the first average energy usage based on one or more energy usage data points.

19. The non-transitory computer readable storage medium of claim 15, wherein allocating the second load of the aggregate load to the first monitored appliance and allocating the third load of the aggregate load to the second monitored appliance comprises:
calculating a first load contribution ratio for the first monitored appliance and a second load contribution ratio for the second monitored appliance;
calculating the second load for the first monitored appliance based on the first load contribution ratio and a total load associated with the period of time; and
calculating the third load for the second monitored appliance based on the second load contribution ratio and the total load associated with the period of time.

20. The non-transitory computer readable storage medium of claim 15, the operations further comprising providing a graphical representation of a total load associated with the period of time on a per-appliance basis.
